(19) United States
(12) Patent Application Publication
(10) Pub. No.: US 2024/0253182 A1
(43) Pub. Date: Aug. 1, 2024

(54) METHOD FOR CONDITIONING POLISHING TOOL, SUBSTRATE PROCESSING METHOD, AND SUBSTRATE PROCESSING DEVICE

(71) Applicant: SCREEN Holdings Co., Ltd., Kyoto (JP)

(72) Inventors: Ryohei HOKAKU, Kyoto-shi (JP); Katsunori TANAKA, Kyoto-shi (JP); Wataru YANO, Kyoto-shi (JP)

(73) Assignee: SCREEN Holdings Co., Ltd., Kyoto (JP)

(21) Appl. No.: 18/419,564

(22) Filed: Jan. 23, 2024

(30) Foreign Application Priority Data
Jan. 27, 2023 (JP) 2023-011058

(51) Int. Cl. B24B 53/017; B24B 37/04

(52) U.S. Cl. CPC B24B 53/017; B24B 37/042

(57) ABSTRACT

A method for conditioning a polishing tool includes: a substrate rotation process, holding a silicon dummy substrate having a main surface in a non-mirror state in a horizontal posture and rotating the dummy substrate about a vertical axis; and a conditioning execution process, executing conditioning of the polishing tool by bringing the polishing tool into contact with the main surface of the dummy substrate that is being rotated, wherein the polishing tool has a resin body in which abrasive grains are dispersed.

### CROSS-REFERENCE TO RELATED APPLICATION

This application claims the priority benefit of Japan application no. 2023-011058, filed on Jan. 27, 2023. The entirety of the above-mentioned patent application is hereby incorporated by reference herein and made a part of this specification.

### BACKGROUND

### Technical Field

The invention relates to a method for conditioning a polishing tool that polishes a back surface of a substrate, a substrate processing method, and a substrate processing device. Examples of substrates include semiconductor substrates, substrates for flat panel displays (FPDs), glass substrates for photomasks, substrates for optical discs, substrates for magnetic discs, ceramic substrates, substrates for solar cells, etc. Examples of FPDs include liquid crystal displays, organic electroluminescence display devices, etc.

### Description of Related Art

Conventionally, there is a defocus issue of being out of focus in the exposure process of photolithography. The defocus issue results from dust adhered to the back surface of the substrate. To remove such dust, a brush process is performed. However, for example, if the dust is embedded in the back surface of the substrate, the dust cannot be removed by using a conventional polyvinyl alcohol (PVA) sponge brush. Therefore, such dust is removed by using a polishing brush (polishing tool) including abrasive grains (see Patent Document 1, for example).

Patent Document 2 discloses a polishing device including a polishing table. When a new polishing pad is attached to the polishing table, the polishing device performs a process to start up the polishing pad by pressing a dummy wafer against the polishing pad of the polishing table that rotates.

### PRIOR ART DOCUMENT(S)

### Patent Document(s)

### [Patent Document 1]

Japanese Laid-open No. 2018-046108

### [Patent Document 2]

Japanese Laid-open No. 2005-288664

In the case of the conventional PVA brush, after brush replacement, a process aiming at increasing the cleanliness of the brush by removing initial contamination of the brush is performed. The processing time is not particularly an issue.

Comparatively, in the case of the polishing brush, conditioning is performed on the brush surface by using a silicon dummy wafer. Conditioning is a process to remove excessive protrusions of abrasive grains included in the polishing brush by abutting the polishing brush against the dummy wafer that rotates, and aims at suppressing the occurrence of scratches at the time of a wafer process. Such conditioning may take four to six hours, for example. Therefore, after polishing brush replacement, the device (or processing unit) is not available for use until processing of a production wafer becomes possible. As a result, the production efficiency deteriorates.

The invention provides a method for conditioning a polishing tool, a substrate processing method, and a substrate processing device capable of reducing the time required for conditioning a polishing tool.

### SUMMARY

A method for conditioning a polishing tool according to an aspect of the invention includes: a substrate rotation process, holding a silicon dummy substrate having a main surface in a non-mirror state in a horizontal posture and rotating the dummy substrate about a vertical axis; and a conditioning execution process, executing conditioning of the polishing tool by bringing the polishing tool into contact with the main surface of the dummy substrate that is being rotated, wherein the polishing tool has a resin body in which abrasive grains are dispersed.

In addition, a substrate processing method according to another aspect of the invention includes: a substrate rotation process, holding a silicon dummy substrate having a main surface in a non-mirror state in a horizontal posture and rotating the dummy substrate about a vertical axis; and a conditioning execution process, executing conditioning of the polishing tool by bringing the polishing tool into contact with the main surface of the dummy substrate that is being rotated, wherein the polishing tool has a resin body in which abrasive grains are dispersed; and a polishing process, polishing a back surface of a production substrate by using the polishing tool on which the conditioning is performed.

In addition, a substrate processing device according to another aspect of the invention includes: a holding and rotating part, holding a silicon dummy substrate having a main surface in a non-mirror state in a horizontal posture and rotating the dummy substrate about a vertical axis; a polishing tool, having a resin body in which abrasive grains are dispersed; a polishing tool movement mechanism, moving the polishing tool; and a control part, controlling substrate processing. The control part executes conditioning of the polishing part by bringing the polishing tool into contact with the main surface of the dummy substrate being rotated by the holding and rotating part by using the polishing tool movement mechanism.

### BRIEF DESCRIPTION OF THE DRAWINGS

FIG. 1 is a view illustrating a schematic configuration of a dummy substrate processing device according to an embodiment.

FIG. 2 is a flowchart illustrating an operation of the dummy substrate processing device.

FIG. 3 is a side view illustrating a chemical solution process to a dummy substrate.

FIG. 4A illustrates measurement results of surface roughnesses (arithmetic mean roughness Ra and maximum height Ry) after a process with ammonia water (chemical solution) is performed.

FIG. 4B indicates measurement positions of FIG. 4A.

FIG. 5 is a view illustrating a schematic configuration of a production substrate processing device according to an embodiment.

FIG. 6 is a side view illustrating a configuration of a processing unit.

FIG. 7 is a plan view illustrating the configuration of the processing unit.

FIG. 8 is a flowchart illustrating an operation of the production substrate processing device.

FIGS. 9A and 9B are views exemplifying the shapes of abrasive particles included in a resin body of a polishing tool.

FIG. 10 is a side view for explaining conditioning of the polishing tool.

FIG. 11 is a graph comparing a dummy substrate having a main surface in a normal mirror state and a dummy substrate having a main surface in a non-mirror state.

### DESCRIPTION OF THE EMBODIMENTS

A method for conditioning a polishing tool according to an aspect of the invention includes: a substrate rotation process, holding a silicon dummy substrate having a main surface in a non-mirror state in a horizontal posture and rotating the dummy substrate about a vertical axis; and a conditioning execution process, executing conditioning of the polishing tool by bringing the polishing tool into contact with the main surface of the dummy substrate that is being rotated, wherein the polishing tool has a resin body in which abrasive grains are dispersed.

According to the method for conditioning the polishing tool, in order to perform conditioning of the polishing tool having the resin body where abrasive grains are dispersed, the silicon dummy substrate having the main surface in the non-mirror state is used. Since the main surface of the non-mirror state is rougher than a mirror surface, compared with the silicon dummy substrate having the main surface in the mirror state, the time required for conditioning can be reduced. Accordingly, the time from the polishing tool is replaced until the production substrate can be processed can be reduced.

In addition, in the method for conditioning the polishing tool, it may also be that the main surface of the dummy substrate in the non-mirror state is formed by processing the main surface of the dummy substrate by using a chemical solution. Without using a special tool, an inexpensive dummy substrate that is easily available at semiconductor factories and the like can be processed and used.

In addition, in the method for conditioning the polishing tool, it may also be that the chemical solution is ammonia water. By processing with ammonia water, the main surface of the dummy substrate in the non-mirror state can be formed.

In addition, in the method for conditioning the polishing tool, it may also be that in the conditioning execution process, the conditioning of the polishing tool is executed by moving the polishing tool between a center of the dummy substrate and an edge of the dummy substrate while bringing the polishing tool into contact with the main surface of the dummy substrate that is being rotated. By moving the polishing tool between the center and the edge of the dummy substrate, the conditioning of the polishing tool can be performed.

In addition, a substrate processing method according to another aspect of the invention includes: a substrate rotation process, holding a silicon dummy substrate having a main surface in a non-mirror state in a horizontal posture and rotating the dummy substrate about a vertical axis; and a conditioning execution process, executing conditioning of the polishing tool by bringing the polishing tool into contact with the main surface of the dummy substrate that is being rotated, wherein the polishing tool has a resin body in which abrasive grains are dispersed; and a polishing process, polishing a back surface of a production substrate by using the polishing tool on which the conditioning is performed.

According to the substrate processing method, in order to perform conditioning of the polishing tool having the resin body where abrasive grains are dispersed, the silicon dummy substrate having the main surface in the non-mirror state is used. Since the main surface of the non-mirror state is rougher than a mirror surface, compared with the silicon dummy substrate having the main surface in the mirror state, the time required for conditioning can be reduced. Accordingly, the time from the polishing tool is replaced until the production substrate can be processed can be reduced. In addition, by using the polishing tool having been subjected to conditioning, the polishing on the back surface of the production substrate can be performed, while scratches can be suppressed.

In addition, a substrate processing device according to another aspect of the invention includes: a holding and rotating part, holding a silicon dummy substrate having a main surface in a non-mirror state in a horizontal posture and rotating the dummy substrate about a vertical axis; a polishing tool, having a resin body in which abrasive grains are dispersed; a polishing tool movement mechanism, moving the polishing tool; and a control part, controlling substrate processing. The control part executes conditioning of the polishing part by bringing the polishing tool into contact with the main surface of the dummy substrate being rotated by the holding and rotating part by using the polishing tool movement mechanism.

According to the substrate processing device, in order to perform conditioning of the polishing tool having the resin body where abrasive grains are dispersed, the silicon dummy substrate having the main surface in the non-mirror state is used. Since the main surface of the non-mirror state is rougher than a mirror surface, compared with the silicon dummy substrate having the main surface in the mirror state, the time required for conditioning can be reduced.

Accordingly, the time from the polishing tool is replaced until the production substrate can be processed can be reduced.

In addition, in the substrate processing device, it may also be that the non-mirror state is a state rougher than a mirror surface. The conditioning of the polishing tool can be performed by using the dummy substrate having the main surface in the non-mirror state rougher than a mirror surface.

In addition, in the substrate processing device, it may also be that the non-mirror state is a state rougher than a back surface of the dummy substrate. The conditioning of the polishing tool can be performed by using the dummy substrate having the main surface in the non-mirror state rougher than the back surface of the dummy substrate.

In addition, the substrate processing device may further include: a dummy substrate storage part, storing the dummy substrate; and a transport robot, transporting the dummy substrate. Also, it may also be that, at a time of performing the conditioning of the polishing tool, the control part transports the dummy substrate from the dummy substrate storage part to the holding and rotating part by using the transport robot, and after performing the conditioning of the polishing tool, the control part transports the dummy substrate from the holding and rotating part to the dummy substrate storage part by using the transport robot.

At the time of performing the conditioning of the polishing tool, the dummy substrate is retrieved from the dummy substrate storage part, and after the conditioning is performed, the dummy substrate can be returned to the dummy substrate storage part.

In addition, the substrate processing device may further include: a carrier, storing a production substrate. In addition, it may also be that, after performing the conditioning of the polishing tool, the control part transports the production substrate from the carrier to the holding and rotating part by using the transport robot, and polishes, by using the polishing tool, a back surface of the production substrate held by the holding and rotating part. By using the polishing tool having been subjected to conditioning, the polishing on the back surface of the production substrate can be performed, while scratches can be suppressed. In addition, a tool that can reduce the time required for conditioning is the dummy substrate. Therefore, the transport robot can handle the dummy substrate like the production substrate.

With the method for conditioning the polishing tool, the substrate processing method, and the substrate processing device, the time required for conditioning the polishing tool can be shortened.

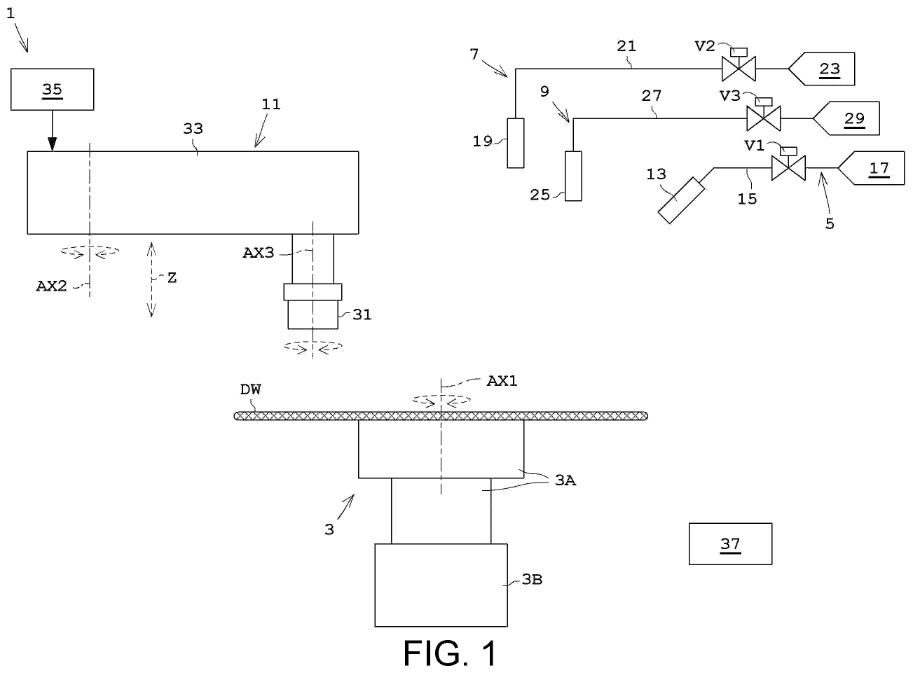

In the following, the embodiments of the invention will be described with reference to the drawings. FIG. 1 is a view illustrating a schematic configuration of a dummy substrate processing device 1 according to an embodiment.

### (1) Configuration of the Dummy Substrate Processing Device

Referring to FIG. 1, firstly, the dummy substrate processing device 1 for creating a dummy substrate (dummy wafer) DW for performing conditioning on a polishing tool 89 to be described afterwards is described. The dummy substrate processing device 1 processes the dummy substrate DW in a disc shape, for example. The dummy substrate processing device 1 includes a holding and rotating part 3, a chemical solution supply part 5, a cleaning liquid supply part 7, a rinse liquid supply part 9, and a brush mechanism 11.

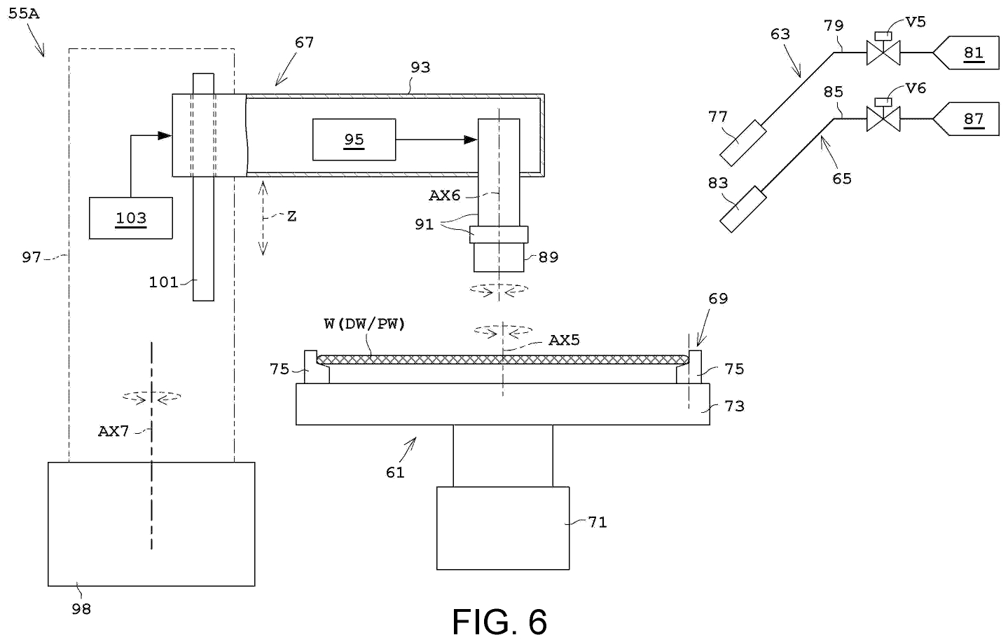

The holding and rotating part 3 holds the dummy substrate DW to rotate the dummy substrate DW about a vertical axis AX1. The holding and rotating part 3 includes a spin chuck 3A and a rotation driving part 3B. The spin chuck 3A is a vacuum chuck that holds the dummy substrate DW by vacuum sucking the back surface of the dummy substrate DW. It is noted that the spin chuck 3A may also be a mechanical chuck (see FIG. 6) or an electrostatic chuck. The rotation driving part 3B rotates the dummy substrate DW held by the spin chuck 3A about the vertical axis AX1. The rotation driving part 3B includes an electric motor.

The chemical solution supply part 5 includes a chemical solution nozzle 13, a chemical solution pipe 15, a chemical solution supply source 17, and an opening/closing valve V1. The chemical solution nozzle 13 discharges a chemical solution to the main surface (front surface) of the dummy substrate DW held by the holding and rotating part 3. As an example, ammonia water is used as the chemical solution. Ammonia water (proportion of ammonia: 2% to 3%) is a solution obtained by diluting ammonia (NH₃) with pure water. However, the chemical solution is not limited to ammonia water. The chemical solution pipe 15 connects the chemical solution nozzle 13 and the chemical solution supply source 17. The chemical supply source 17 supplies the chemical solution to the chemical solution nozzle 13 via the chemical solution pipe 15. The opening/closing valve V1 is provided at the chemical solution pipe 15.

The cleaning liquid supply part 7 includes a cleaning liquid nozzle 19, a cleaning liquid supply pipe 21, a cleaning liquid supply source 23, and an opening/closing valve V2. The cleaning liquid nozzle 19 discharges a cleaning liquid to the main surface of the dummy substrate DW held by the holding and rotating part 3. As an example, SC1 is used as the cleaning liquid. SC1 is a liquid mixture of ammonia, hydrogen peroxide (H₂O₂), and water. The cleaning liquid pipe 21 connects the cleaning liquid nozzle 19 and the cleaning liquid supply source 23. The opening/closing valve V2 is provided at the cleaning liquid pipe 21.

The rinse liquid supply part 9 includes a rinse liquid nozzle 25, a rinse liquid pipe 27, a rinse liquid supply source 29, and an opening/closing valve V3. The rinse liquid nozzle 25 discharges a rinse liquid to the main surface of the dummy substrate DW held by the holding and rotating part 3. As an example, pure water, such as deionized water (DIW), is used as the rinse liquid. The rinse liquid pipe 27 connects the rinse liquid nozzle 25 and the rinse liquid supply source 29. The opening/closing valve V3 is provided at the rinse liquid pipe 27.

Each of the three opening/closing valves V1, V2, V3 and two opening/closing valves V5, V6 to be described afterwards supplies a liquid and stops supplying the liquid. The chemical solution nozzle 13 is fixed to a position on the outer side of the dummy substrate DW. The nozzles 19, 25 are respectively moved in the horizontal direction (X-Y direction) and the upper-lower direction (Z-direction) by using a nozzle movement part (having an electric motor) not shown herein. Like the two nozzles 19, 25, the chemical solution nozzle 13 may also be moved by the nozzle movement part. In addition, the two nozzles 19, 25 may also be respectively fixed to positions on the outer side of the dummy substrate DW.

The brush mechanism 11 includes a brush 31, an arm 33, and a brush movement part 35. As an example, a polyvinyl alcohol (PVA) sponge brush is used as the brush 31. The brush 31 is formed in a cylindrical shape. The arm 33 supports the brush 31. The brush movement part 35, for example, revolves the brush 31 via the arm 33 about a vertical axis AX2 on the outer side of the dummy substrate DW held by the holding and rotating part 3. The brush movement part 35 moves the brush 31 in the upper-lower direction. In addition, the brush movement part 35 rotates the brush 31 about a vertical axis AX3 passing through a central line of the brush 31. The brush movement part 35 includes three electric motors, for example. Except for a polishing tool 89, the brush mechanism 11 may also be configured to be the same as a back surface polishing mechanism 67 to be described afterwards.

The dummy substrate processing device 1 includes a control part 37 and a storage part (not shown). The control part 37 controls the process on the dummy substrate DW. The control part 37 includes one or more processors, such as a central processing unit (CPU). The storage part includes at least one of a read-only memory (ROM), a random access memory (RAM), and a hard disk. The storage part stores a computer program necessary for the control part 37 to control the respective components of the dummy substrate processing device 1.

### (2) Operation of the Dummy Substrate Processing Device

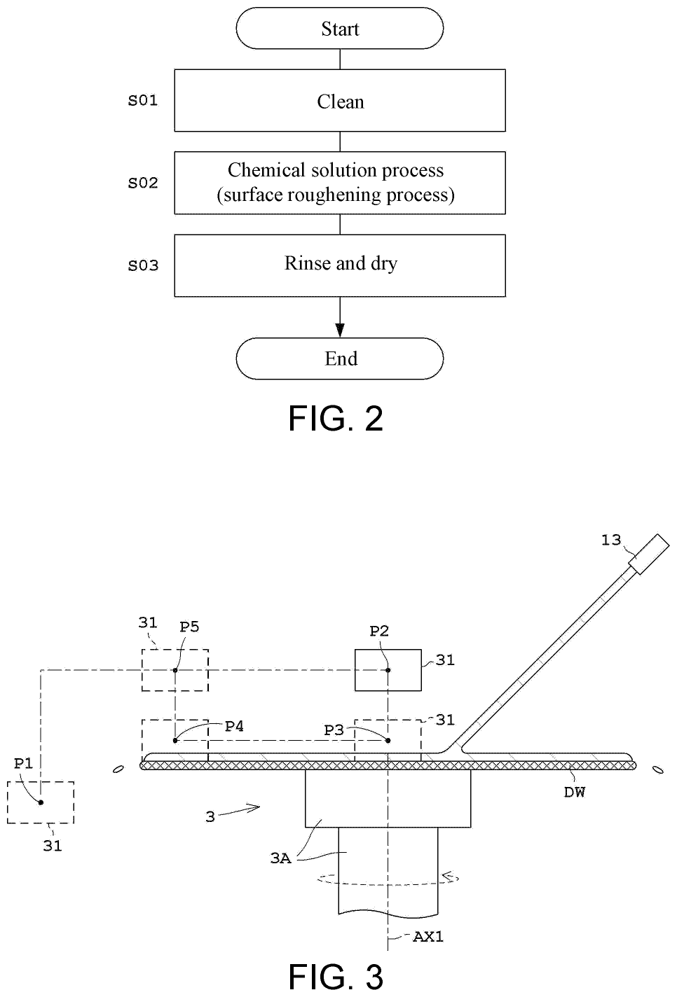

In the following, an operation of the dummy substrate processing device 1 is described with reference to the flowchart of FIG. 2, etc. FIG. 2 is a flowchart illustrating an operation of the dummy substrate processing device 1. FIG. 3 is a side view illustrating a chemical solution process to the dummy substrate DW.

### [Step S01] Clean

The dummy substrate DW is transported onto the spin chuck 3A of the holding and rotating part 3. The spin chuck 3A holds the back surface of the dummy substrate DW through vacuum suction. At this time, the main surface of the dummy substrate DW faces upward, and the back surface of the dummy substrate DW faces downward. The dummy substrate DW is a bare silicon substrate. In addition, the main surface of the dummy substrate DW is a mirror surface. That is, the main surface is not epitaxially grown, but remains in a state where mirror fining is performed by a polishing device in a manufacturing process of the dummy substrate DW. Nevertheless, the main surface of the dummy substrate DW may also be epitaxially grown.

The rotation driving part 3B of the holding and rotating part 3 rotates the dummy substrate DW held by the spin chuck 3A about the vertical axis AX1. In addition, the cleaning liquid nozzle 19 is moved above the center of the dummy substrate DW by using a nozzle movement part not shown herein. Then, by opening the opening/closing valve V2, the cleaning liquid nozzle 19 discharges SC1 as the cleaning liquid onto the dummy substrate DW held by the spin chuck 3A. The SC1 discharged onto the dummy substrate DW spreads on the main surface of the dummy substrate DW through rotation. Accordingly, the main surface of the dummy substrate DW is cleaned. In addition, redundant SC1 is scattered from the main surface of the dummy substrate DW through the rotation of the dummy substrate DW. Then, by closing the opening/closing valve V2, the cleaning liquid nozzle 19 stops discharging SC1. It is noted that while SC1 includes ammonia, a reaction that roughens the main surface of the dummy substrate DW is not performed.

### [Step S02] Chemical Solution Process (Roughening Process)

Then, by opening the opening/closing valve V1, the chemical solution nozzle 13 discharges ammonia water at room temperature (23° C.), as the chemical solution to the vicinity of the center of the dummy substrate DW held and rotated by the holding and rotating part 3. Accordingly, the ammonia water spreads through the rotation of the dummy substrate DW, and SC1 on the main surface of the dummy substrate DW is replaced by ammonia water. In addition, redundant ammonia water is scattered from the main surface of the dummy substrate DW through the rotation of the dummy substrate DW. The ammonia water performs a roughening process (etching process) on the main surface of the dummy substrate DW. The discharge of ammonia water onto the main surface of the dummy substrate DW is performed for five hours, for example. After about one hour, the main surface in the mirror state starts becoming cloudy. That is, the main surface starts being cloudified.

When the ammonia water is being discharged onto the main surface of the dummy substrate DW, the brush 31 scans the main surface. Detailed description is as follows. As shown in FIG. 3, the brush movement part 35 of the brush mechanism 11 moves the brush 31 from a standby position P1 to a top position P2 at the center of the dummy substrate DW. In addition, the brush movement part 35 rotates the brush 31 about the vertical axis AX3.

Then, by lowering the brush 31 from the top position P2 to a central position P3, the brush movement part 35 brings the lower surface of the brush 31 into contact with the mains ruface of the dummy substrate DW. Then, in the state in which the brush 31 is in contact with the dummy substrate DW, the brush movement part 35 moves the brush 31 from the central position P3 to an edge position P4 of the dummy substrate DW. Then, by raising the brush 31 from the position P4 to a top position P5 thereabove, the brush movement part 35 moves the brush 31 away from the dummy substrate DW.

During the period in which the ammonia water is being supplied onto the main surface of the dummy substrate DW, the brush movement part 35 repeats the movement of the brush 31 in the order of the top position P2, the central position P3, the edge position P4, and the edge top position P5. The scan of the brush 31 can further spread the ammonia water over the entire main surface of the dummy substrate DW. Where necessary, it may also be that the brush 31 is brought into contact with ammonia water, and the scan of the brush 31 is performed in a state in which the lower surface of the brush 31 is slightly lifted from the main surface of the dummy substrate DW. In addition, the scan of the brush 31 may also be omitted.

By closing the opening/closing valve V1 after the ammonia water is discharged for a predetermined time (e.g., 5 hours), the chemical solution nozzle 13 stops discharging ammonia water. Together with this, the brush movement part 35 moves the brush 31 back to the standby position P1. The rotation of the dummy substrate DW is continued.

### [Step S03] Rinse and Dry

The rinse liquid nozzle 25 is moved to the top position with respect to the center of the dummy substrate DW by using a nozzle movement part not shown herein. The rinse liquid nozzle 25 is moved without interference with the brush 31, etc. By opening the opening/closing valve V3 after the discharge of ammonia water stops, the rinse liquid nozzle 25 discharges pure water (e.g., DIW) onto the main surface of the dummy substrate DW that is being rotated. Accordingly, the pure water spreads on the main surface of the dummy substrate DW through rotation. Therefore, the ammonia water on the dummy substrate DW is replaced by pure water. Redundant pure water is scattered from the dummy substrate DW through rotation.

Then, by closing the opening/closing valve V3, the rinse liquid nozzle 25 stops discharging pure water. Then, the rotation driving part 3B of the holding and rotating part 3 rotates the dummy substrate DW at a high speed, thereby shaking off the pure water attached to the dummy water DW. Accordingly, spin drying is performed. Then, the rotation driving part 3B stops the rotation of the dummy substrate DW. Then, the spin chuck 3A releases the dummy substrate DW from being held.

Accordingly, the dummy substrate DW for conditioning the polishing tool 89 is made. The main surface of the dummy substrate DW in a non-mirror state is formed by the process on the main surface of the dummy substrate DW by using a chemical solution. That is, by using the chemical solution (ammonia water), the main surface of the dummy substrate DW is roughened from the normal mirror state into the non-mirror state. Accordingly, without using a special tool, an inexpensive dummy substrate DW that is easily available at semiconductor factories and the like can be processed and used. For example, although text reflected on the main surface can be read at the time of the mirror state, the text reflected on the main surface cannot be read at the time of the non-mirror state as the main surface is like frosted glass.

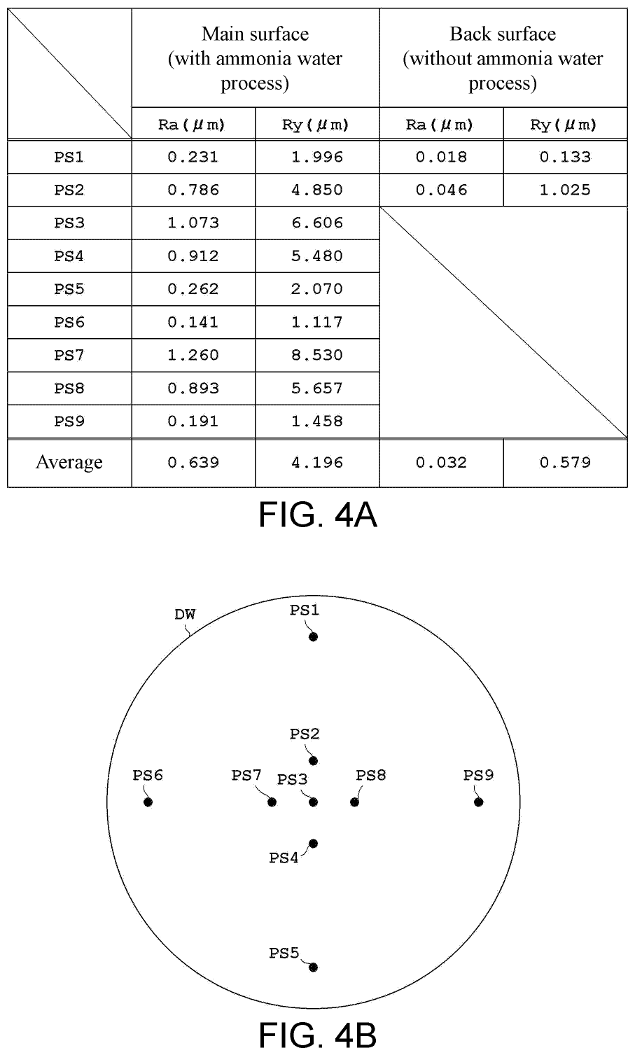

FIG. 4A illustrates measurement results of surface roughness (arithmetic mean roughness Ra and maximum height Ry) after a process with ammonia water (chemical solution) is performed. FIG. 4B indicates measurement positions PS1 to PS9 of FIG. 4A. The maximum height Ry is a width (difference) between the maximum and minimum of surface unevenness. In FIG. 4A, the average of the surface roughness (arithmetic mean roughness) Ra of the main surface of the dummy substrate DW is 0.639 m (micrometer).

Comparatively, although an attempt is made to measure the surface roughness Ra of the main surface of the dummy substrate DW before the process with ammonia water, measurement is not possible due to the measurement accuracy (resolution) of the measurement device. Therefore, the surface roughness Ra after the process with ammonia water (chemical solution) is compared based on on-line information at the home page. According to Information 1 (see below for URL), the surface roughness Ra of the silicon wafer is 0.140 nm (nanometer). According to Information 2 (see below for URL), the surface roughness Ra after a chemical mechanical polishing (CMP) process on the silicon wafer is 0.22 nm (nanometer). Therefore, it is known that the main surface of the dummy substrate DW subjected to the process (roughening process) with ammonia water is rougher than the surface of a silicon substrate in the normal mirror state after the CMP process.
(i) URL of Information 1: (https://www.ube.co.jp/usal/documents/s264_121.htm)
(i) URL of Information 2: (https://www.ipros.jp/news/detail/49335/)

In FIG. 4A, the average of the surface roughness Ra of the back surface of the dummy substrate DW is 0.032 m (micrometer). Therefore, the main surface after being subjected to the process with ammonia water is rougher than the back surface without the process with ammonia water. That is, the non-mirror state of the main surface of the dummy substrate DW is rougher than the back surface of the dummy substrate DW. The back surface is a surface opposite to the main surface.

### (3) Configuration of a Production Substrate Processing Device

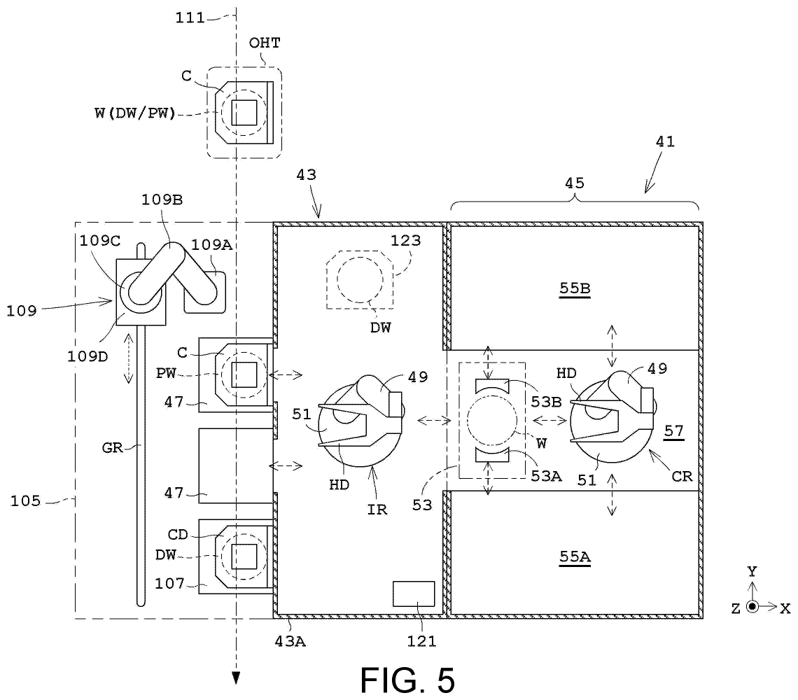

In the following, a production substrate processing device 41 is described with reference to FIG. 5. The production substrate processing device 41 executes conditioning of the polishing tool 89 by using the dummy substrate DW in the non-mirror state, and polishes the back surface of a production substrate (production wafer) W by using the polishing tool 89 having been subjected to conditioning. The production substrate processing device 41 includes an indexer block 43 and a processing block 45. The production substrate processing device 41 corresponds to the substrate processing device of the invention.

### (3-1) Configuration of the Indexer Block

The indexer block 43 includes two carrier mounting shelves 47 and an indexer robot IR. Each carrier mounting shelf 47 is a shelf for mounting a carrier C that stores the substrate W.

The carrier C stores multiple (e.g., 25) substrates W in a horizontal posture at predetermined intervals along a vertical direction Z. Although a front open unified pod (FOUP) is used as the carrier C, a container other than FOUP, such as a standard mechanical interface (SMIF) pod, may also be used. Also, among the substrates W, the dummy substrate DW is distinguished from a production substrate PW in which electronic circuits are formed on the main surface. The expression “substrate W” is used in the case where the dummy substrate DW and the production substrate PW are not distinguished.

The indexer robot IR moves the substrate W between the carrier C mounted in the carrier mounting shelf 47 and a reversing unit 53. The indexer robot IR includes a hand HD holding the substrate W, a multi-joint arm 49 moving the hand HD, and a lifting platform 51 that lifts and lowers the hand HD.

The hand HD is movable for transporting the substrate W. The hand HD is installed to the tip end of the multi-joint arm 49. The multi-joint arm 49 is formed of a scalar type. The multi-joint arm 49 moves the hand HD in a horizontal direction (X-Y direction). In addition, the multi-joint arm 49 changes the orientation of the hand HD by rotating the hand HD about a vertical axis. The lifting platform 51 supports the base end of the multi-joint arm 49. The lifting platform 51 lifts or lowers the hand HD in the upper-lower direction (Z-direction) via the multi-joint arm 49. The multi-joint arm 49 and the lifting platform 51 includes one or more electric motors as a driving source. Although the hand HD is moved by the multi-joint arm 49, the hand HD may also be configured to be able to advance, retreat, and rotate about a vertical axis.

### (3-2) Configuration of the Processing Block

The processing block 45 includes a center robot CR, the reversing unit 53, and two processing units 55A, 55B. The center robot CR is disposed in a transport region 57 extending in X-direction from the indexer robot IR. The reversing unit 53 reverses the front and back sides of the substrate W. The reversing unit 53 includes a pair of chucks 53A, 53B disposed along Y-direction. The reversing unit 53 sandwiches the edge of the substrate W by using the chucks 53A, 53B and holds the substrate W, and then rotates the chucks 53A, 53B holding the substrate W about an axis extending along Y-direction. The reversing unit 53 is disposed between the indexer robot IR and the center robot CR.

The center robot CR transports the substrate W between the reversing unit 53 and the two processing units 55A, 55B. The center robot CR is configured in the same way as the indexer robot IR.

### (3-2-1) Configurations of Processing Units

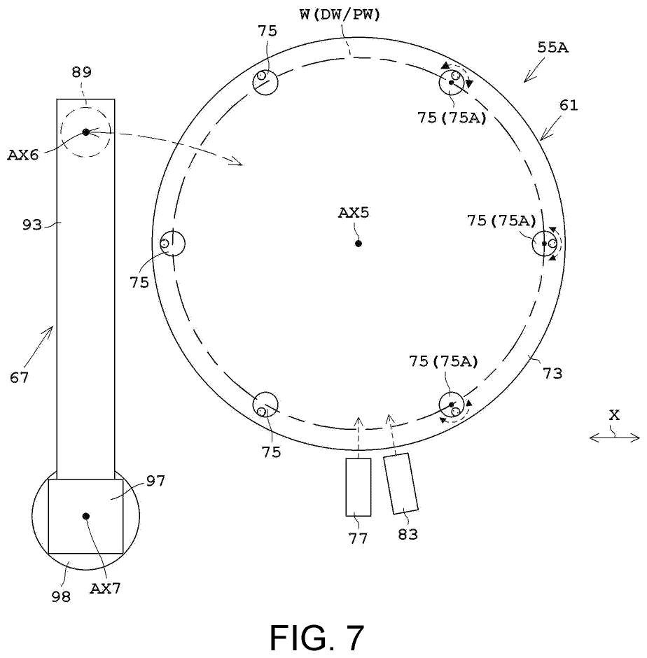

FIG. 6 is a side view illustrating a schematic configuration of the first processing unit 55A. FIG. 7 is a plan view thereof. The second processing unit 55B may also be configured in the same way as the first processing unit 55A. In addition, the second processing unit 55B may also be configured differently from the first processing unit 55A.

The first processing unit 55A performs conditioning of the polishing tool 89, and polishes the back surface of the production substrate PW. The first processing unit 55A includes a holding and rotating part 61, a cleaning liquid supply part 63, a rinse liquid supply part 65, and a back surface polishing mechanism 67. The holding and rotating part 61 holds the substrate W and rotates the substrate W about a vertical axis AX5.

The holding and rotating part 61 includes a spin chuck (mechanical chuck) 69 and a rotation driving part 71. The rotation driving part 71 includes an electric motor. By rotating the spin chuck 69, the rotation driving part 71 rotates the substrate W held by the spin chuck 69 about the vertical axis AX5.

The spin chuck 69 includes a spin base 73 and three or more (six, for example) holding pins 75. The spin base 73 is formed in a disc shape. The vertical axis AX5 passes through the center of the spin base 73 (i.e., the substrate W). As shown in FIG. 7, the six holding pins 75 are erected at equal intervals in a ring shape about the vertical axis AX5. In addition, each of three holding pins 75A, for example, among the six holding pins 75 rotates about a vertical axis that passes through itself. Accordingly, the spin chuck 69 holds the substrate W by sandwiching the edge of the substrate W in the horizontal direction by using the six holding pins 75. The spin chuck 69 may be the spin chuck 3A (vacuum chuck) as shown in FIG. 1 or an electrostatic chuck.

The cleaning liquid supply part 63 includes a cleaning liquid nozzle 77, a cleaning liquid supply pipe 79, a cleaning liquid supply source 81, and the opening/closing valve V5. The cleaning liquid nozzle 77 discharges a cleaning liquid to the substrate W held by the holding and rotating part 61. As an example, SC1 or pure water (e.g., DIW) is used as the cleaning liquid. The cleaning liquid pipe 79 connects the cleaning liquid nozzle 77 and the cleaning liquid supply source 81. The cleaning liquid supply source 81 supplies the cleaning liquid to the cleaning liquid nozzle 77. The opening/closing valve V5 is provided at the cleaning liquid pipe 79.

The rinse liquid supply part 65 includes a rinse liquid nozzle 83, a rinse liquid pipe 85, a rinse liquid supply source 87, and the opening/closing valve V6. The rinse liquid nozzle 83 discharges the rinse liquid to the substrate W held by the holding and rotating part 61. As an example, pure water (e.g., DIW) is used as the rinse water. The rinse liquid pipe 85 connects the rinse liquid nozzle 83 and the rinse liquid supply source 87. The rinse liquid supply source 87 supplies the rinse liquid to the rinse liquid nozzle 83. The opening/closing valve V6 is provided at the rinse liquid pipe 85. Although the cleaning liquid nozzle 77 and the rinse liquid nozzle 83 are fixed, the cleaning liquid nozzle 77 and the rinse liquid nozzle 83 may also be movable by a nozzle movement part not shown herein.

The back surface polishing mechanism 67 includes the polishing tool (polishing brush) 89, a shaft 91, an arm 93, and an electric motor 95. The polishing tool 89 has a resin body in which abrasive grains are dispersed. The polishing tool 89, for example, has a resin body of polyvinyl alcohol (PVA) in which abrasive grains of silicon carbide (SiC) are dispersed. PVA is a thermally curable resin. The abrasive grains are not limited to SiC, but may also be, for example, cerium oxide (CeO₂), silicon dioxide (SiO₂), diamond. The resin is not limited to PVA. For example, a phenol resin may also be used. The resin body may also be sponge-like.

The upper end of the polishing tool 89 is installed to the lower end of the shaft 91 extending in the vertical direction. The upper part of the shaft 91 is held to be rotatable about the vertical axis AX6 by using the arm 93 extending in a horizontal direction. The shaft 91 is rotated about the vertical axis AX6 by the electric motor 95 via a belt or a gear, for example. The polishing tool 89 and the shaft 91 are provided on the tip end side of the arm 93.

The back surface polishing mechanism 67 further includes a lifting driving part (linear actuator) 97 and a revolving driving part 98. The lifting driving part 97 lifts and lowers the polishing tool 89 and the arm 93, etc. The lifting driving part 97 includes a guide rail 101 and a driving part 103. The base end of the arm 93 is liftably supported by the guide rail 101. The guide rail 101 guides the arm 93 in the upper-lower direction. The driving part 103 includes an electric motor and a screw shaft, for example. The driving part 103 may also be an air cylinder.

The revolving driving part 98 is provided on the outer side of the substrate W held by the holding and rotating part 61. The revolving driving part 98 revolves the polishing tool 89, the arm 93, and the lifting driving part 97, etc., about a vertical axis AX7. The revolving driving part 98 includes an electric motor. The lifting driving part 97 and the revolving driving part 98 are equivalent to a polishing tool movement mechanism of the invention. The polishing tool movement mechanism moves the polishing tool 89.

### (3) Configuration of a Stocker

Referring to FIG. 5 again, the production substrate processing device 41 further includes a stocker 105. The stocker 105 includes a carrier storage shelf 107 and a carrier transport robot 109. The carrier storage shelf 107 is provided on an outer wall 43A of the indexer block 43. The carrier storage shelf 107 is a shelf for storing the carrier C. A dummy substrate carrier CD is mounted on the carrier storage shelf 107. The dummy substrate carrier CD is a carrier C storing the dummy substrate DW for conditioning. The indexer robot IR cannot access the carrier C mounted in the carrier storage shelf 107. The dummy substrate carrier CD is equivalent to the dummy substrate storage part of the invention.

The carrier transport robot 109 transports the carrier C between the two carrier mounting shelves 47 and the carrier storage shelf 107. The carrier transport robot 109 includes a movable holding part 109A, a multi-joint arm 109B, a lifting platform 109C, and a Y-direction movement part 109D. The holding part 109A holds the carrier C. The multi-joint arm 109B horizontally moves the holding part 109A. The lifting platform 109C lifts and lowers the holding part 109A and the multi-joint arm 109B in the upper-lower direction. The Y-direction movement part 109D moves the holding part 109A and the lifting platform 109C, etc., along a guide rail GR extending in Y-direction. Each of the holding part 109A, the multi-joint arm 109B, the lifting platform 109C, and the Y-direction movement part 109D includes one or more electric motors.

As shown in FIG. 5, for example, a rail 111 is provided above the two carrier mounting shelves 47 and the carrier storage shelf 107. An external transport mechanism OHT (overhead hoist transport) moves along the rail 111, and transports the carrier C to (or from) the respective shelves 47, 107. The external transport mechanism OHT includes a holding part (not shown) holding the carrier C. The holding part is lifted and lowered.

### (3-4) Control Part

The production substrate processing device 41 includes a control part 121 and a storage part (not shown). The control part 121 controls a process of the substrate W. The control part 121 includes one or more processors, such as a central processing unit (CPU). The storage part includes at least one of a read-only memory (ROM), a random access memory (RAM), and a hard disk. The storage part stores a computer program necessary for the control part 121 to control the respective components of the production substrate processing device 41. The storage part stores modes for executing the conditioning of the polishing tool 89 and modes for polishing the back surface of the production substrate PW.

### (4) Operation of the Production Substrate Processing Device

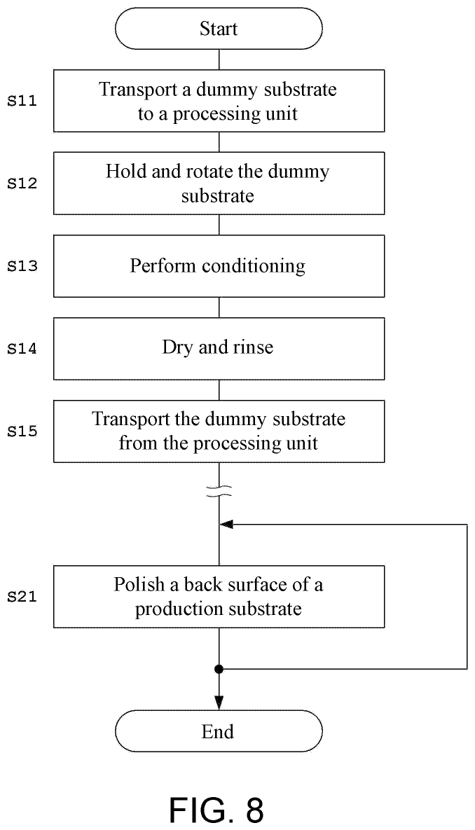

In the following, an operation of the production substrate processing device 41 is described with reference to the flowchart of FIG. 8, etc. In the embodiment, the dummy substrate carrier CD shown in FIG. 5 is mounted in the carrier storage shelf 107. The polishing tool 89 of the back surface polishing mechanism 67 shown in FIG. 6 is replaced. A new polishing tool 89 without being subjected to conditioning is installed to the shaft 91.

### [Step S11] Transport the Dummy Substrate to the Processing Unit

At the time of conditioning the new polishing tool 89, the carrier transport robot 109 transports the dummy substrate carrier CD from the carrier storage shelf 107 to one of the two carrier mounting shelves 47. Inside the dummy substrate carrier CD, the main surface of the dummy substrate DW faces upward, and the back surface faces downward. In addition, the dummy substrate DW is a silicon dummy substrate having been subjected to the chemical solution process in the dummy substrate processing device 1 and being in the non-mirror state (rough state). The non-mirror state is a state rougher than the mirror state.

Then, the indexer robot IR transports the dummy substrate DW from the dummy substrate carrier CD mounted in the carrier mounting shelf 47 to the reversing unit 53. At the time of conditioning the new polishing tool 89, the reversing unit 53 does not reverse the dummy substrate DW. Then, the center robot CR transports the dummy substrate DW from the reversing unit 53 to the holding and rotating part 61 of the first processing unit 55A.

### [Step S12] Hold and Rotate the Dummy Substrate

The, as shown in FIGS. 6 and 7, the holding and rotating part 61 holds the dummy substrate DW to rotate the dummy substrate DW about the vertical axis AX5. At this time, the main surface of the dummy substrate DW in the non-mirror state faces upward, and the back surface of the dummy substrate DW faces downward.

### [Step S13] Perform Conditioning

The opening/closing valve V5 is opened. Accordingly, SC1 (cleaning liquid) is discharged from the cleaning liquid nozzle 77 to the main surface of the dummy substrate DW. Through rotation, SC1 spreads on the main surface of the dummy substrate DW, and the redundant liquid is dispersed out of the dummy substrate DW. By moving the polishing tool 89 between the center of the dummy substrate DW and the edge of the dummy substrate DW while bringing the polishing tool 89 into contact with the main surface of the dummy substrate DW that is rotated, the back surface polishing mechanism 67 performs the conditioning.

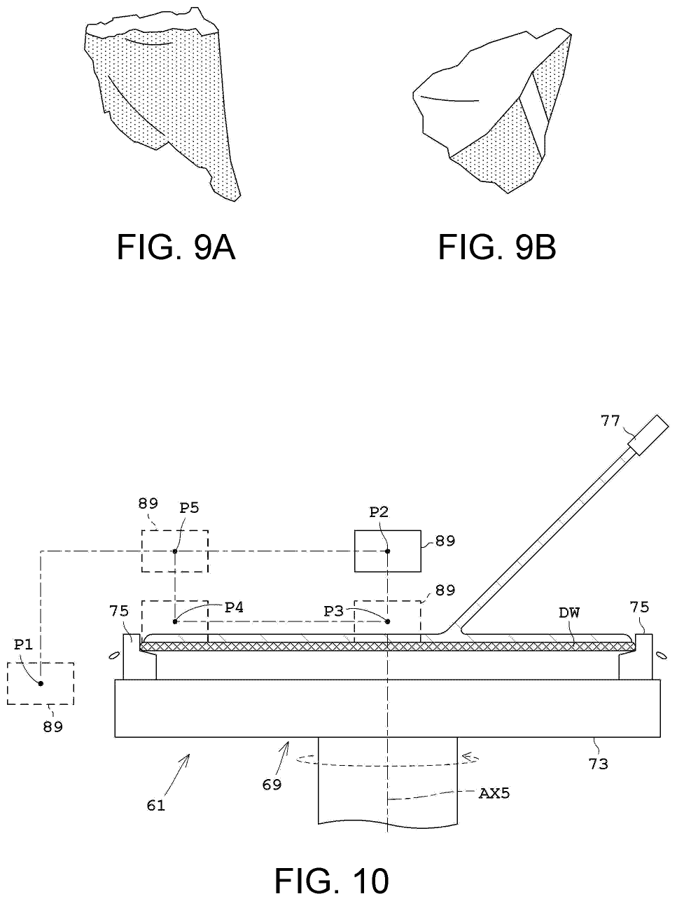

Conditioning is a process to remove excessive protrusions of the abrasive grains included in the polishing the resin body of the polishing tool 89 by abutting the polishing brush against the dummy wafer. As shown in FIGS. 9A and 9B, abrasive grains have protrusions (corners). The conditioning process is also referred to as aging.

The specific operation of the back surface polishing mechanism 67 is described. As shown in FIG. 10, the back surface polishing mechanism 67 (the lifting driving part 97 and the revolving driving part 98) moves the polishing tool 89 from the standby position P1 to the top position P2 at the center of the dummy substrate DW. The electric motor 95 of the back surface polishing mechanism 67 rotates the polishing tool 89 about the vertical axis AX6. Then, in the state in which SC1 is discharged to the main surface of the dummy substrate DW from the cleaning liquid nozzle 77, the back surface polishing mechanism 67 lowers the polishing tool 89 from the top position P2 to the central position P3. Accordingly, the lower surface of the polishing tool 89 contacts the main surface of the dummy substrate DW in the non-mirror state. The back surface polishing mechanism 67 presses the polishing tool 89 against the main surface of the dummy substrate DW by using a pressure set in advance (e.g., 200 mN).

Then, the back surface polishing mechanism 67 moves the polishing tool 89 from the central position P3 to the edge position P4. One movement of the polishing tool 89 from the central position P3 to the edge position P4 is one scan. Then, the back surface polishing mechanism 67 lifts the polishing tool 89 from the edge position P4 to the top position P5 thereabove. Then the back surface polishing mechanism 67 repetitively moves the polishing tool 89 in the order of the central top position P2, the central position P3, the edge position P4, and the edge top position P5 until a time period set in advance has passed.

The polishing tool 89 performs conditioning on the main surface of the dummy substrate DW in a non-mirror state (rough state). Therefore, compared with the case where conditioning is performed on the normal main surface of the dummy substrate DW in the mirror state, the time required for conditioning can be reduced to about ⅙, for example.

### [Step S14] Rinse and Dry

After the movement (scan) of the polishing tool 89 is performed until the time period set in advance has passed, the back surface polishing mechanism 67 moves the polishing tool 89 to the standby position P1. In addition, the opening/closing valve V5 is closed, and the opening/closing valve V6 is opened. Accordingly, the discharge of SC1 from the cleaning liquid nozzle 77 is stopped, and pure water is discharged from the rinse liquid nozzle 83 to the main surface of the dummy substrate DW. The pure water on the main surface of the dummy substrate DW spreads through rotation, and the SC1 on the main surface of the dummy substrate DW is replaced by pure water. Redundant pure water is scattered out of the dummy substrate DW through rotation.

Then, the opening/closing valve V6 is closed, and the discharge of the pure water from the rinse liquid nozzle 83 is stopped. Then, by rotating the dummy substrate DW held by the spin chuck 69 at a high speed, the holding and rotating part 61 dries the dummy substrate DW. Then, the holding and rotating part 61 stops the rotation of the dummy substrate DW. Then, the holding and rotating part 61 releases the dummy substrate DW from being held.

[Step S15] Transport the Dummy Substrate from the Processing Unit

After the conditioning of the polishing tool 89 is performed, the center robot CR transports the dummy substrate DW from the holding and rotating part 61 of the first processing unit 55A to the reversing unit 53. At this time, the main surface of the dummy substrate DW faces upward. Therefore, the reversing unit 53 does not reverse the dummy substrate DW. The indexer robot IR transports the dummy substrate DW from the reversing unit 53 to the dummy substrate carrier CD mounted in the carrier mounting shelf 47. Then, the carrier transport robot 109 transports (returns) the dummy substrate carrier CD from the carrier mounting shelf 47 to the carrier storage shelf 107. Accordingly, a series of operations for conditioning the polishing tool 89 end.

### [Step S21] Polish the Back Surface of the Production Substrate

After the conditioning of the polishing tool 89 is performed, that is, after the series of operations (Steps S11 to S15) for conditioning the polishing tool 89, the polishing tool 89 is used to polish the back surface of the production substrate PW held by the holding and rotating part 61. Then, the polishing on the back surface of the production substrate PW is described.

For example, while moving along the guide rail 111, the external transport mechanism OHT transports the carrier C storing the production substrate PW to one of the two carrier mounting shelves 47. Then, the indexer robot IR transports the production substrate PW from the carrier C mounted in the carrier mounting shelf 47 to the reversing unit 53. At this time, the main surface of the production substrate PW faces upward, and the back surface of the production substrate PW faces downward. It is noted that the main surface of the production substrate PW is a surface (device surface) where electronic circuits are formed.

The reversing unit 53 reverses the front and back sides of the production substrate PW. Accordingly, the back surface of the production substrate PW faces upward. The center robot CR transports the production substrate PW from the reversing unit 53 to the holding and rotating part 61 of the first processing unit 55A. Then, the holding and rotating part 61 holds the production substrate PW to rotate the production substrate PW about the vertical axis AX5. For example, the opening/closing valve V6 is opened and discharges pure water from the rinse liquid nozzle 83 to the back surface of the production substrate PW that is being rotated.

In the state in which pure water is discharged to the back surface of the production substrate PW, the back surface polishing mechanism 67 brings the polishing tool 89 into contact with the back surface of the production substrate PW that is being rotated. In addition, the back surface polishing mechanism 67 moves the polishing tool 89 between the center of the production substrate PW and the edge of the production substrate PW while bringing the polishing tool 89 into contact with the back surface. The movement of the polishing tool 89 is performed like the movement of the polishing tool 89 that is conditioned as shown in FIG. 10. In addition, the polishing tool 89 is rotated about the vertical axis AX6. Since the polishing tool 89 is subjected to conditioning, scratches can be suppressed from being generated on the back surface of the production substrate PW. In addition, by polishing the back surface of the production substrate PW, dust that cannot be removed by using a conventional PVA sponge brush can be removed. Therefore, the defocus issue during an extreme ultraviolet (EV) exposure process, for example, can be resolved.

After the back surface of the production substrate PW is polished, the back surface polishing mechanism 67 moves the polishing tool 89 to the standby position P1. In addition, the opening/closing valve V6 is closed, and the discharge of pure water from the rinse liquid nozzle 83 is stopped. Then, the holding and rotating part 67 rotates the production substrate PW at a high speed, and the production substrate PW is dried. Then, the holding and rotating part 61 releases the production substrate PW from being held after the rotation of the production substrate PW is stopped.

Then, the center robot CR transports the production substrate PW from the holding and rotating part 61 of the processing unit 55A to the reversing unit 53. The reversing unit 53 reverses the production substrate PW whose back surface faces upward, so that the main surface (device surface) of the production substrate PW faces upward. Then, the indexer robot IR transports (returns) the production substrate PW from the reversing unit 53 to the carrier C mounted in the carrier mounting shelf 47. Then, the external transport mechanism OHT transports the carrier C from the carrier mounting shelf 47 to the next destination.

According to the embodiment, in order to perform conditioning of the polishing tool 89 having the resin body where abrasive grains are dispersed, the silicon dummy substrate DW having the main surface in the non-mirror state is used. Since the main surface of the non-mirror state is rougher than a mirror surface, compared with the silicon dummy substrate having the main surface in the mirror state, the time required for conditioning can be reduced. Accordingly, the time from the polishing tool 89 is replaced until the production substrate PW can be processed can be reduced. Therefore, the production efficiency can be facilitated.

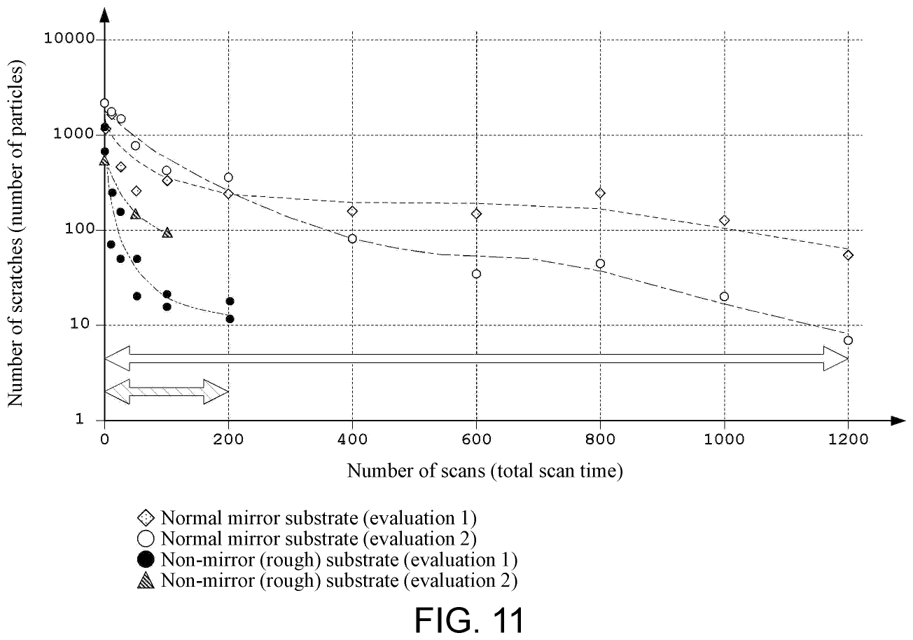

FIG. 11 is a graph comparing the dummy substrate having the main surface in the normal mirror state (referred to as “normal mirror substrate” in the following) and the dummy substrate DW having the main surface in the non-mirror state (referred to as “non-mirror (rough) substrate” in the following). In FIG. 11, the horizontal axis indicates the number of scans, i.e., the total scan time. In addition, the vertical axis indicates the number of scratches. The number of scratches indicates the value counted as particles in a particle measurement device.

When the positions counted as particles in the particle measurement device are observed by using a scanning electron microscope (SEM), about 90% of the positions are scratches. Therefore, the positions counted as particles can be said as substantially scratches.

In FIG. 11, for example, a total of 400 scans are performed by bringing the new polishing tool 89 (the PVA resin body in which abrasive grains of SiC are dispersed) into contact with the normal mirror substrate. In such case, the number of scratches (number of particles) is measured for a substrate for particle evaluation after a predetermined polishing process is performed on a different, new normal mirror substrate (the substrate for particle evaluation) by using the polishing tool 89 after 400 scans. The same applies to the case of the non-mirror substrate.

According to FIG. 11, when the normal mirror substrate is used to perform conditioning of the new polishing tool 89, with 1200 scans being performed, the predetermined number of scratches is measured. Comparatively, when the non-mirror (rough) substrate DW of the embodiment is used to perform conditioning of the new polishing tool 89, the predetermined number of scratches can be achieved with about 200 scans. That is, according to the non-mirror substrate DW of the embodiment, the conditioning of the polishing tool 89 is performed for about ⅙ of time.

In addition, the production substrate processing device 41 includes the dummy substrate carrier CD storing the dummy substrate DW and the indexer robot IR and the center robot CR for transporting the dummy substrate DW. At the time of performing the conditioning of the polishing tool 89, the control part 121 transports the dummy substrate DW from the dummy substrate carrier CD to the holding and rotating part 61 by using the two robots (the indexer robot IR and the center robot CR), and after the performing the conditioning of the polishing tool 89, the control part 121 transports the dummy substrate DW from the holding and rotating part 61 to the dummy carrier CD by using the two robots (the indexer robot IR and the center robot CR).

At the time of performing the conditioning of the polishing tool 89, the dummy substrate DW is retrieved from the dummy substrate carrier CD, and after the conditioning is performed, the dummy substrate DW can be returned to the dummy substrate carrier CD.

In addition, the production substrate processing device 41 includes the carrier C storing the production substrate PW. After performing the conditioning of the polishing tool 89, the control part 121 transports the production substrate PW from the carrier C to the holding and rotating part 61 by using the two robots (the indexer robot IR and the center robot CR) and polishes, by using the polishing tool 89, the back surface of the production substrate PW held by the holding and rotating part 61. By using the polishing tool 89 having been subjected to conditioning, the polishing on the back surface of the production substrate PW can be performed, while scratches can be suppressed. In addition, a tool that can reduce the time required for conditioning is the dummy substrate DW. Therefore, the two robots (the indexer robot IR and the center robot CR) can handle the dummy substrate DW like the production substrate PW.

The invention is not limited to the above embodiment, and modifications as follows can be made.

(1) In the above embodiment, the dummy substrate DW is held by the spin chuck 3A (the holding and rotating part 3), and the chemical solution is discharged to the main surface of the dummy substrate DW being rotated, thereby performing the chemical solution process (surface roughening process) on the main surface of the dummy substrate DW. Regarding this point, it may also be that the chemical solution (such as room-temperature ammonia water) is stored in a chemical solution tank, and multiple dummy substrates in a vertical posture are jointly immersed into the chemical solution stored in the chemical solution tank to perform the chemical solution process. That is, it may also be that multiple dummy substrates are batch-processed. At the time of batch-processing, a protection sheet may be adhered to the back surface of each dummy substrate, so that the back surface of each dummy substrate is not subjected to the chemical solution process.

(2) In the above embodiment and Modified Example (1), as shown in FIG. 10, the polishing tool 89 scans from the central position P3 to the edge position P4. Regarding this point, it may also be that the polishing tool 89 scans from the edge position P4 to the central position P3. In addition, the polishing tool 89 may also reciprocally scan between the central position P3 and the edge position P4. The same applies to the brush 31.

(3) In the production substrate processing device 41 of the embodiment and the respective modified examples, the dummy substrate DW having the main surface in the non-mirror state is stored in the dummy substrate carrier CD. At this time, the production substrate PW is not stored in the dummy substrate carrier CD. In addition, the dummy substrate carrier CD is mounted in the carrier storage shelf 107 of the stocker 105. For example, it may also be that the dummy substrate DW is stored in the carrier C together with the production substrate PW.

Also, the dummy substrate DW may also be stored in a substrate storage part 123 as indicated by a broken line inside the indexer block 43. At the time of performing the conditioning of the polishing tool 89, the indexer robot IR may retrieve the dummy substrate DW from the substrate storage part 123. After the conditioning of the polishing tool 89 is performed, the indexer robot IR may return the dummy substrate DW to the substrate storage part 123. The substrate storage part 123 may also be the carrier C.

(4) In the production substrate processing device 41 of the embodiment and the respective modified examples, the dummy substrate carrier CD storing the dummy substrate DW is mounted in the carrier storage shelf 107. Regarding this point, it may also be that the dummy substrate carrier CD is transported to one of the carrier mounting shelves 47 by using the external transport mechanism OHT.

(5) In the production substrate processing device 41 of the embodiment and the respective modified examples, the production substrate processing device 41 is provided separately from the dummy substrate processing device 1. Regarding this, it may also be that the processing block 45 of the production substrate processing device 41 includes the dummy substrate processing device 1 as a processing unit. In such case, the control part 121 also controls the dummy substrate processing device 1. In addition, the substrate processing device of the invention may also include the dummy substrate processing device 1 and the production substrate processing device 41.

(6) In the production substrate processing device 41 of the embodiment and the respective modified examples, the indexer robot IR and the center robot CR transport the dummy substrate DW between the dummy substrate carrier CD mounted in the carrier mounting shelf 47 and the holding and rotating part 61. Regarding this, it may also be that one of the indexer robot IR and the center robot CR transports the dummy substrate DW between the dummy substrate carrier CD and the holding and rotating part 61. In such case, the reversing unit 53 is disposed at a position not interfering with the transport of the substrate W. It is noted that one of the indexer robot IR and the center robot CR is equivalent to the transport robot of the invention.

What is claimed is:

1. A method for conditioning a polishing tool, comprising:
a substrate rotation process, holding a silicon dummy substrate having a main surface in a non-mirror state in a horizontal posture and rotating the dummy substrate about a vertical axis; and
a conditioning execution process, executing conditioning of the polishing tool by bringing the polishing tool into contact with the main surface of the dummy substrate that is being rotated, wherein the polishing tool has a resin body in which abrasive grains are dispersed.

2. The method for conditioning the polishing tool as claimed in claim 1, wherein the main surface of the dummy substrate in the non-mirror state is formed by processing the main surface of the dummy substrate by using a chemical solution.

3. The method for conditioning the polishing tool as claimed in claim 2, wherein the chemical solution is ammonia water.

4. The method for conditioning the polishing tool as claimed in claim 1, wherein in the conditioning execution process, the conditioning of the polishing tool is executed by moving the polishing tool between a center of the dummy substrate and an edge of the dummy substrate while bringing the polishing tool into contact with the main surface of the dummy substrate that is being rotated.

5. A substrate processing method, comprising:
a substrate rotation process, holding a silicon dummy substrate having a main surface in a non-mirror state in a horizontal posture and rotating the dummy substrate about a vertical axis;
a conditioning execution process, executing conditioning of the polishing tool by bringing the polishing tool into contact with the main surface of the dummy substrate that is being rotated, wherein the polishing tool has a resin body in which abrasive grains are dispersed; and
a polishing process, polishing a back surface of a production substrate by using the polishing tool on which the conditioning is performed.

6. A substrate processing device, comprising a holding and rotating part, holding a silicon dummy substrate having a main surface in a non-mirror state in a horizontal posture and rotating the dummy substrate about a vertical axis;
a polishing tool, having a resin body in which abrasive grains are dispersed;
a polishing tool movement mechanism, moving the polishing tool; and
a control part, controlling substrate processing,
wherein the control part executes conditioning of the polishing part by bringing the polishing tool into contact with the main surface of the dummy substrate being rotated by the holding and rotating part by using the polishing tool movement mechanism.

7. The substrate processing device as claimed in claim 6, wherein the non-mirror state is a state rougher than a mirror surface.

8. The substrate processing device as claimed in claim 6, wherein the non-mirror state is a state rougher than a back surface of the dummy substrate.

9. The substrate processing device as claimed in claim 6, further comprising:
a dummy substrate storage part, storing the dummy substrate; and
a transport robot, transporting the dummy substrate,
wherein, at a time of performing the conditioning of the polishing tool, the control part transports the dummy substrate from the dummy substrate storage part to the holding and rotating part by using the transport robot, and after performing the conditioning of the polishing tool, the control part transports the dummy substrate from the holding and rotating part to the dummy substrate storage part by using the transport robot.

10. The substrate processing device as claimed in claim 9, further comprising:
a carrier, storing a production substrate,
wherein, after performing the conditioning of the polishing tool, the control part transports the production substrate from the carrier to the holding and rotating part by using the transport robot, and polishes, by using the polishing tool, a back surface of the production substrate held by the holding and rotating part.
